(19) United States
(12) Patent Application Publication
(10) Pub. No.: US 2006/0038198 A1
(43) Pub. Date: Feb. 23, 2006

(54) Device and method for producing output light having a wavelength spectrum in the visible range and the infrared range using a fluorescent material

(76) Inventors: Janet Bee Yin Chua, Perak (MY); Kok Chin Pan, Penang (MY); Kee Yean Ng, Penang (MY); Kheng Leng Tan, Penang (MY); Tajul Arosh Baroky, Penang (MY)

Correspondence Address: AGILENT TECHNOLOGIES, INC.;Intellectual Property Administration, Legal Department, DL429, P.O. Box 7599, Loveland, CO, 80537-0599, US

(21) Appl. No.: 10/924,556

(22) Filed: Aug. 23, 2004

(51) Int. Cl. H01L 33/00

(52) U.S. Cl. 257/100

(57) ABSTRACT

A device and method for producing output light having a wavelength spectrum in the visible wavelength range and the infrared wavelength range uses a fluorescent material to convert at least some of the original light emitted from a light source of the device to longer wavelength light to produce the output light. The light source may be configured to generate light having a peak wavelength in an ultraviolet-and-visible wavelength range. The fluorescent material may include any combination of red, green, blue and yellow phosphors.

### BACKGROUND OF THE INVENTION

Existing light emitting diodes (“LEDs”) can emit light in the ultraviolet (“UV”), visible or infrared (“IR”) wavelength range. These LEDs generally have narrow emission spectrum (approximately ±10 nm). As an example, a blue InGaN LED may generate light with wavelength of 470 nm±10 nm. As another example, a green InGaN LED may generate light with wavelength of 510 nm±10 nm. As another example, a red AlInGaP LED may generate light with wavelength of 630 nm±10 nm.

However, in some applications, it is desirable to have LEDs that can generate broader emission spectrums, such as a broad emission spectrum in the visible wavelength range to produce white light. Due to the narrow-band emission characteristics, these monochromatic LEDs cannot be directly used for “white” light applications. Rather, the output light of a monochromatic LED must be mixed with other light of one or more different wavelengths to produce white light. Two common approaches for producing white light using monochromatic LEDs include (1) packaging individual red, green and blue LEDs together so that light emitted from these LEDs are combined to produce white light and (2) introducing fluorescent material into a UV, blue or green LED so that some of the original light emitted by the semiconductor die of the LED is converted into longer wavelength light and combined with the original UV, blue or green light to produce white light.

Between these two approaches for producing white light using the monochromatic LEDs, the second approach is generally preferred over the first approach. In contrast to the second approach, the first approach requires a more complex driving circuitry since the red, green and blue LEDs include semiconductor dies that have different operating voltages requirements. In addition to having different operating voltage requirements, the red, green and blue LEDs degrade differently over their operating lifetime, which makes color control over an extended period difficult using the first approach. Moreover, since only a single type of monochromatic LED is needed for the second approach, a more compact device can be made using the second approach that is simpler in construction and lower in manufacturing cost.

In other applications, LEDs that can generate broad emission spectrums that includes portions of both the visible and IR wavelength ranges may be desired. As an example, the visible light of the LEDs can be used for visual communication or visual effect, while the IR light can be used with IR detectors for signal transmission. Consequently, there is a need for a device and method for emitting output light having a broad emission spectrum in both the visible and IR wavelength ranges.

### SUMMARY OF THE INVENTION

A device and method for producing output light having a wavelength spectrum in the visible wavelength range and the infrared wavelength range uses a fluorescent material to convert at least some of the original light emitted from a light source of the device to longer wavelength light to produce the output light. The light source may be configured to generate light having a peak wavelength in an ultraviolet-and-visible wavelength range. The fluorescent material may include any combination of red, green, blue and yellow phosphors, depending on the light source.

A device in accordance with an embodiment of the invention includes a light source that generates original light, and a wavelength-shifting region optically coupled to the light source to receive the original light. The wavelength-shifting region including a fluorescent material having a wavelength-converting property to convert at least some of the original light to converted light to produce the output light, which has a wavelength spectrum in the visible wavelength range and the infrared wavelength range.

A device in accordance with another embodiment of the invention includes a semiconductor die that emits original light having a peak wavelength in the ultraviolet and visible wavelength range, and a wavelength-shifting region optically coupled to the light source to receive the original light. The wavelength-shifting region includes a fluorescent material having a wavelength-converting property to convert at least some of the original light to converted light to produce the output light, which has a wavelength spectrum in the visible wavelength range and the infrared wavelength range.

A method for producing output light in accordance with an embodiment of the invention includes generating original light, receiving the original light, including converting at least some of the original light into converted light by fluorescence, and emitting the original light and the converted light as components of the output light, which has a wavelength spectrum in the visible wavelength range and the infrared wavelength range

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a diagram of an LED with an emission spectrum in the visible wavelength range and the infrared (IR) wavelength range in accordance with an embodiment of the invention.

FIGS. 2A, 2B and 2C are diagrams of LEDs with alternative lamp configurations in accordance with an embodiment of the invention.

FIGS. 3A, 3B, 3C and 3D are diagrams of LEDs with a leadframe having a reflector cup in accordance with an alternative embodiment of the invention.

FIG. 4 is a flow diagram of a method for producing output light having a wavelength spectrum in the visible wavelength range and the IR wavelength range in accordance with an embodiment of the invention.

### DETAILED DESCRIPTION

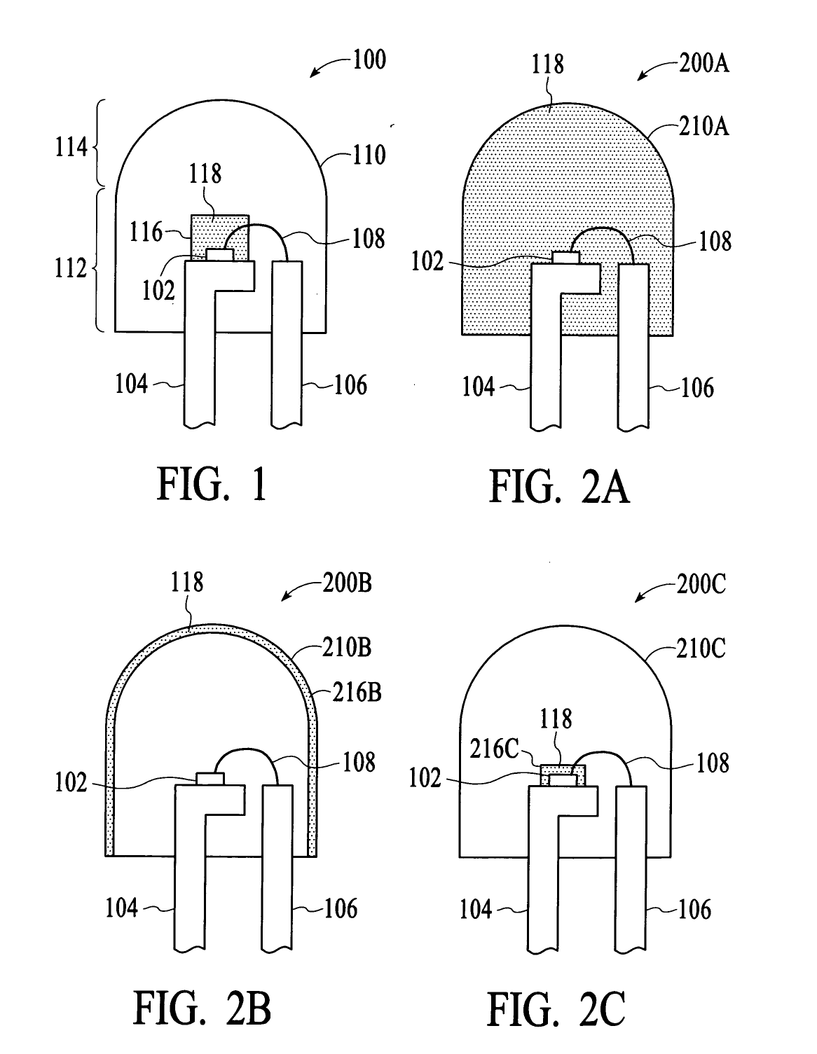

With reference to FIG. 1, a light emitting diode (LED) 100 in accordance with an embodiment of the invention is shown. The LED 100 produces output light having a broad wavelength spectrum in both the visible wavelength range and the infrared (IR) wavelength range. Thus, the output light of the LED 100 includes both visible and IR light. The output light is produced using a fluorescent material to convert some of the original light generated by the LED 100 into different wavelength light. The converted light modifies the wavelength spectrum of the original light to produce the desired wavelength spectrum of the output light. Since the output light includes not only visible light but also IR light, the LED 100 can be used for IR applications, such as for IR signal transmission, as well as for visual light applications, such as for visual communication or visual effect.

As shown in FIG. 1, the LED 100 is a leadframe-mounted LED. The LED 100 includes an LED die 102, leadframes 104 and 106, a wire 108 and a lamp 110. The LED die 102 is a semiconductor chip that generates light of a particular peak wavelength. Thus, the LED die 102 is a light source for the LED 100. Although the LED 100 is shown to include a single LED die, the LED may include more than one LED die, e.g., one ultraviolet (UV) LED die and one visible LED die. The light from the LED die 102 generally has a narrow wavelength spectrum (approximately ±10 nm). The LED die 102 may be designed to generate light having a peak wavelength in the ultraviolet and visible wavelength range (˜100-700 nm). As an example, the LED die 102 may be a GaN-based LED, such as an InGaN or AlGaN LED, that generates light having a peak wavelength in the UV, blue or green wavelength range. As another example, the LED die 102 may be an AlInGaP die that generates light having a peak wavelength in the red, orange or yellow wavelength range.

The LED die 102 is situated on the leadframe 104 and is electrically connected to the other leadframe 106 via the wire 108. The leadframes 104 and 106 provide the electrical power needed to drive the LED die 102. The LED die 102 is encapsulated in the lamp 110, which is a medium for the propagation of light from the LED die 102. The lamp 110 includes a main section 112 and an output section 114. In this embodiment, the output section 114 of the lamp 110 is dome-shaped to function as a lens. Thus, the light emitted from the LED 100 as output light is focused by the dome-shaped output section 114 of the lamp 110. However, in other embodiments, the output section 114 of the lamp 100 may be horizontally planar.

The lamp 110 of the LED 100 is made of a transparent substance, which can be any transparent material, such as clear epoxy, silicone or glass, so that light from the LED die 102 can travel through the lamp and be emitted out of the output section 114 of the lamp. In this embodiment, the lamp 110 includes a wavelength-shifting region 116, which is also a medium for propagating light, made of a mixture of the transparent substance and a fluorescent material 118. The fluorescent material 118 in the wavelength-shifting region 116 is used to convert at least some of the original light emitted by the LED die 102 to lower energy (longer wavelength) light. The amount of original light converted by the fluorescent material 118 may be varied, depending on the desired output light of the LED 100. For example, if the LED die 102 is an UV LED die, then virtually all of the original light may be converted by the fluorescent material 118 since UV light is harmful to the eyes, and thus, UV light is not desired in the output light. The converted light and unabsorbed light, if any, are emitted from the light output section 114 of the lamp 110 as output light of the LED 100.

The fluorescent material 118 in the wavelength-shifting region 116 may be composed of one or more inorganic phosphors, one or more fluorescent organic dyes, one or more hybrid phosphors one or more nano-phosphors, or any combination of fluorescent organic dyes, inorganic phosphors, hybrid phosphors and nano-phosphors. A hybrid phosphor is defined herein as a phosphor made of any combination of inorganic phosphors and organic phosphors or dyes. Regardless of the composition, the fluorescent material 118 has a wavelength-converting property to convert some or virtually all of the original light from the LED die 102 such that the wavelength spectrum of the output light includes the visible wavelength range and the IR range. The wavelength spectrum of the output light from the LED 100 depends on both the wavelength-converting property of the fluorescent material 118 in the wavelength-shifting region 116, as well as the peak wavelength of the original light generated by the LED die 102. Thus, in order to produce output light having a desired wavelength spectrum, the fluorescent material 118 and the LED die 102 must both be taken into account.

The following are some examples of LED die and fluorescent material that can be used together to produce output light having a broad wavelength spectrum in the visible wavelength range and the IR wavelength range in accordance with the invention. As used herein, the visible wavelength range is approximately 400 nm to 700 nm, and the IR wavelength range is approximately 700 nm to 1,600 nm. In the following examples, the color associated with each LED die is the peak wavelength of the light generated by that LED die. Similarly, the color associated with each phosphor is the peak wavelength of the light converted by that phosphor. The first example is a blue LED die and a fluorescent material of red and yellow phosphors, red and green phosphors, or red, yellow and green phosphors. This combination produces output light having a wavelength spectrum in the 400-950 nm range. The second example is a red LED and a fluorescent material of red phosphor. This combination produces output light having a wavelength spectrum in the 600-1500 nm range. The third example is a deep UV LED and a fluorescent material of red, blue and yellow phosphors, red, blue and green phosphors, or red, blue, green and yellow phosphors. This combination produces output light having a wavelength spectrum in the 400-800 nm range. As an example, the yellow phosphor may be: YAG:Ce; TAG:Ce; or YAG:Ce, Pr; the red phosphor may be: CaS:Eu²⁺, Mn²⁺; SrS:Eu²⁺; (Zn, Cd)S:Ag; Mg₄GeO_{5.5}F: MN⁴⁺; ZnSe:Cu; or ZnSeS:Cu,Cl; and the green phosphor may be ZnS:Cu⁺; SrGa₂S₄:Eu²⁺; YAG:Ce³⁺; or BaSrGa₄S₇:Eu; and the blue phosphor may be BaMg₂Al₁₆O₂₇:Eu. However, any fluorescent substance having the desired wavelength-converting property may be used instead of the above examples.

Although the wavelength-shifting region 116 of the lamp 110 is shown in FIG. 1 as being rectangular in shape, the wavelength-shifting region may be configured in other shapes, such as a hemisphere. Furthermore, in other embodiments, the wavelength-shifting region 116 may not be physically coupled to the LED die 102. Thus, in these embodiments, the wavelength-shifting region 116 may be positioned elsewhere within the lamp 110.

In FIGS. 2A, 2B and 2C, LEDs 200A, 200B and 200C with alternative lamp configurations in accordance with an embodiment of the invention are shown. The LED 200A of FIG. 2A includes a lamp 210A in which the entire lamp is a wavelength-shifting region. Thus, in this configuration, the entire lamp 210A is made of the mixture of the transparent substance and the fluorescent material 118. The LED 200B of FIG. 2B includes a lamp 210B in which a wavelength-shifting region 216B is located at the outer surface of the lamp. Thus, in this configuration, the region of the lamp 210B without the fluorescent material 118 is first formed over the LED die 102 and then the mixture of the transparent substance and the fluorescent material 118 is deposited over this region to form the wavelength-shifting region 216B of the lamp. The LED 200C of FIG. 2C includes a lamp 210C in which a wavelength-shifting region 216C is a thin layer of the mixture of the transparent substance and fluorescent material 118 coated over the LED die 102. Thus, in this configuration, the LED die 102 is first coated or covered with the mixture of the transparent substance and the fluorescent material 118 to form the wavelength-shifting region 216C and then the remaining part of the lamp 210C can be formed by depositing the transparent substance without the fluorescent material 118 over the wavelength-shifting region. As an example, the thickness of the wavelength-shifting region 216C of the LED 200C can be between ten (10) and sixty (60) microns.

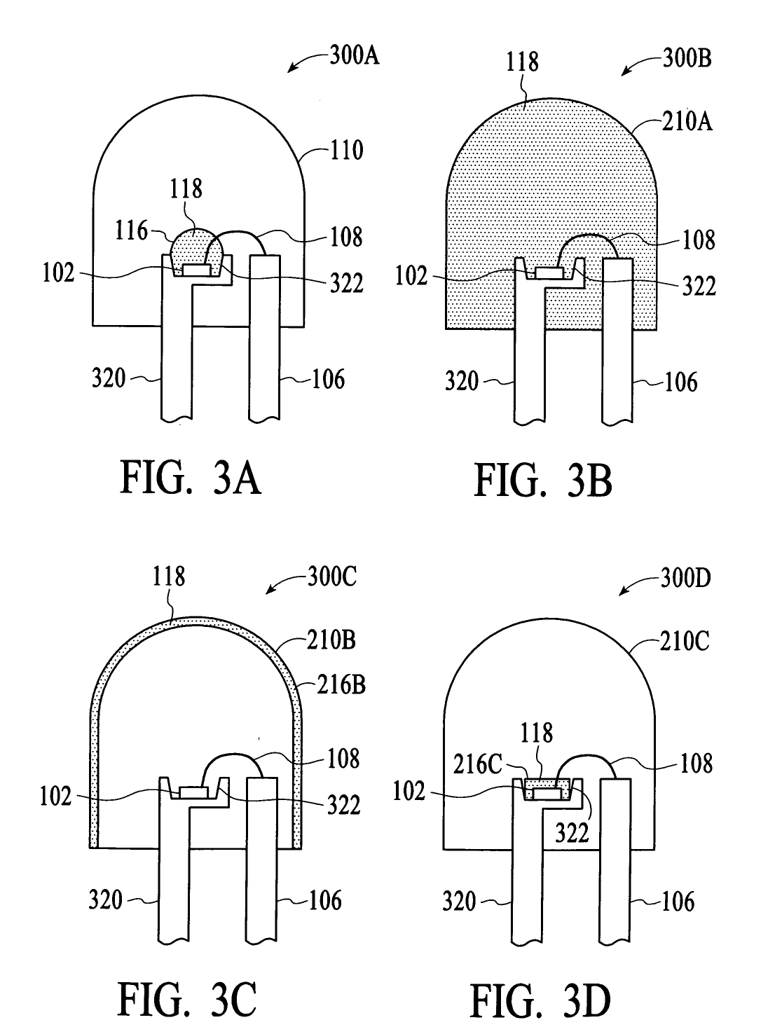

In an alternative embodiment, the leadframe of a LED on which the LED die is positioned may include a reflector cup, as illustrated in FIGS. 3A, 3B, 3C and 3D. FIGS. 3A-3D show LEDs 300A, 300B, 300C and 300D with different lamp configurations that include a leadframe 320 having a reflector cup 322. The reflector cup 322 provides a depressed region for the LED die 102 to be positioned so that some of the light generated by the LED die is reflected away from the leadframe 320 to be emitted from the respective LED as useful output light.

The different lamp configurations described above can be applied other types of LEDs, such as surface-mounted LEDs, to produce other types of LEDs in accordance with the invention. In addition, these different lamp configurations may be applied to other types of light emitting devices, such as semiconductor lasing devices, in accordance with the invention. In these light emitting devices, the light source can be any light source other than an LED die, such as a laser diode.

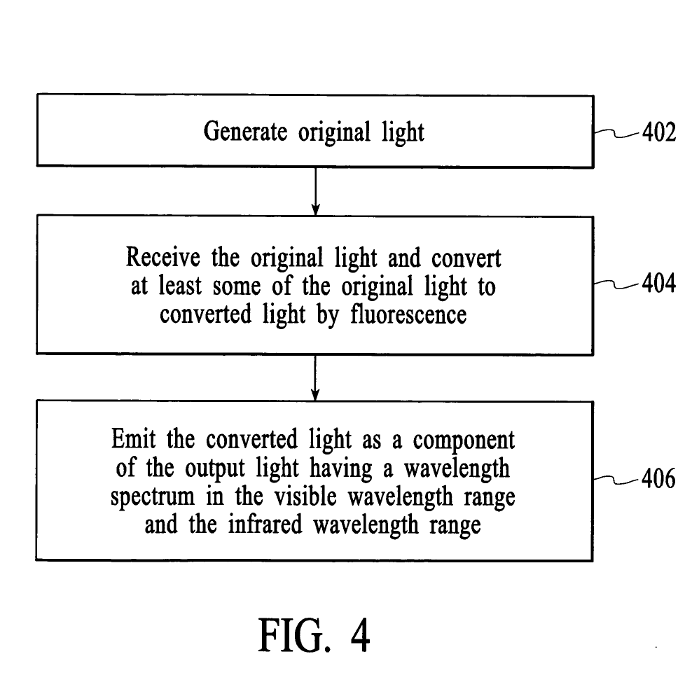

A method for producing output light having a wavelength spectrum in the visible wavelength range and the IR wavelength range in accordance with an embodiment of the invention is described with reference to FIG. 4. At block 402, original light is generated. The original light may be generated from an LED die, such as a UV LED die, a blue LED die or a red LED die. Next, at block 404, the original light is received and at least some of the first light is converted to converted light by fluorescence. The converting of the original light may be achieved using one or more phosphors, such as red, blue, yellow and green phosphors. Next, at block 406, the converted light is emitted as a component of the output light having a wavelength spectrum in the visible wavelength range and the IR wavelength range.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A device for emitting output light, said device comprising:
a light source that generates original light; and
a wavelength-shifting region optically coupled to said light source to receive said original light, said wavelength-shifting region including a fluorescent material having a wavelength-converting property to convert at least some of said original light to converted light to produce said output light, said output light having a wavelength spectrum in the visible wavelength range and the infrared wavelength range.

2. The device of claim 1 wherein said light source includes one or more light emitting diode dies that can generate said original light having a peak wavelength in the ultraviolet and/or visible wavelength range.

3. The device of claim 1 wherein said fluorescent material includes one of a fluorescent organic dye, an inorganic phosphor, a hybrid phosphor and a nano-phosphor.

4. The device of claim 1 wherein said light source is configured to generate said original light having a peak wavelength in the blue wavelength range, and wherein said fluorescent material includes any combination of red, yellow and green phosphors.

5. The device of claim 1 wherein said light source is configured to generate said original light having a peak wavelength in the ultraviolet wavelength range, and wherein said fluorescent material includes any combination of red, blue, yellow and green phosphors.

6. The device of claim 1 wherein said light source is configured to generate said original light having a peak wavelength in a particular color wavelength range of the visible light spectrum, and wherein said fluorescent material includes a phosphor that can produce said converted light having a peak wavelength in said particular color wavelength range.

7. The device of claim 6 wherein said light source is configured to generate said original light having a peak wavelength in the red wavelength range, and wherein said fluorescent material includes a red phosphor.

8. A device for emitting output light, said device comprising:
a semiconductor die that emits original light having a peak wavelength in the ultraviolet and visible wavelength range; and
a wavelength-shifting region optically coupled to said light source to receive said original light, said wavelength-shifting region including a fluorescent material having a wavelength-converting property to convert at least some of said original light to converted light to produce said output light, said output light having a wavelength spectrum in the visible wavelength range and the infrared wavelength range.

9. The device of claim 8 wherein said semiconductor die is a light emitting diode die.

10. The device of claim 8 wherein said fluorescent material includes one of a fluorescent organic dye, an inorganic phosphor, a hybrid phosphor and a nano-phosphor.

11. The device of claim 8 wherein said semiconductor die is configured to generate said original light having a peak wavelength in the blue wavelength range, and wherein said fluorescent material includes any combination of red, yellow and green phosphors.

12. The device of claim 8 wherein said semiconductor die is configured to generate said original light having a peak wavelength in the ultraviolet wavelength range, and wherein said fluorescent material includes any combination of red, blue, yellow and green phosphors.

13. The device of claim 8 wherein said semiconductor die is configured to generate said original light having a peak wavelength in a particular color wavelength range of the visible light spectrum, and wherein said fluorescent material includes a phosphor that can produce said converted light having a peak wavelength in said particular color wavelength range.

14. The device of claim 13 wherein said semiconductor die is configured to generate said original light having a peak wavelength in the red wavelength range of the visible light spectrum, and wherein said fluorescent material includes a red wavelength phosphor.

15. A method for producing output light, said method comprising:
generating original light;
receiving said original light, including converting at least some of said original light into converted light by fluorescence; and
emitting said converted light as a component of said output light, said output light having a wavelength spectrum in the visible wavelength range and the infrared wavelength range.

16. The method of claim 15 wherein said generating includes generating said original light having a peak wavelength in the ultraviolet and/or visible wavelength range.

17. The method of claim 15 wherein said converting includes converting at least some of said original light into said converted light using one of a fluorescent organic dye, an inorganic phosphor, a hybrid phosphor and a nano-phosphor.

18. The method of claim 15 wherein said generating includes generating said original light having a peak wavelength in the blue wavelength range, and wherein said converting includes converting at least some of said original light into said converted light using any combination of red, yellow and green phosphors.

19. The method of claim 15 wherein said generating includes generating said original light having a peak wavelength in the ultraviolet wavelength range, and wherein said converting includes converting at least some of said original light into said converted light using any combination of red, blue, yellow and green phosphors.

20. The method of claim 15 wherein said generating includes generating said original light having a peak wavelength in a particular color wavelength range, and wherein said converting includes converting at least some of said original light into said converted light using a phosphor that can produce said converted light having a peak wavelength in said particular color wavelength range.
